(19) United States
(12) Patent Application Publication
(10) Pub. No.: US 2012/0012923 A1
(43) Pub. Date: Jan. 19, 2012

(54) SEMICONDUCTOR DEVICE AND METHOD FOR FORMING THE SAME

(75) Inventor: Seong Wan RYU, Yongin (KR)

(73) Assignee: Hynix Semiconductor Inc., Icheon-si (KR)

(21) Appl. No.: 12/951,943

(22) Filed: Nov. 22, 2010

(30) Foreign Application Priority Data
Jul. 14, 2010 (KR) 10-2010-0067859

(51) Int. Cl. H01L 29/78; H01L 21/336

(52) U.S. Cl. 257/329; 438/268; 257/E29.262; 257/E21.41

(57) ABSTRACT

The present invention relates to a semiconductor device and a method for forming the same. The semiconductor device includes: a vertical pillar protruded from a semiconductor substrate; a first junction region provided at an upper part of the vertical pillar; a second junction region provided in a lower part of the vertical pillar to be separated apart from the first junction region; and a gate oxidation layer in which a thickness thereof in a surface of the vertical pillar in which the first junction region is provided being thicker than that in a surface of the vertical pillar in which the first junction region is not provided. The present invention forms a gate oxidation layer using the oxidation rate difference without a mask process to minimize GIDL that leads to improvement in the characteristic of a semiconductor device.

### CROSS-REFERENCES TO RELATED APPLICATIONS

The present application claims priority to Korean patent application number 10-2010-0067859, filed on Jul. 14, 2010, which is incorporated by reference in its entirety.

### BACKGROUND OF THE INVENTION

The present invention relates to a semiconductor device and a method for forming the same, and more particularly, to a semiconductor device including a vertical gage and a method of forming the same.

As semiconductor devices become highly integrated, the size of active regions are decreased. The channel length of a transistor on the active region is also decreased. As the channel length of transistors is reduced, the short channel effect and the source/drain punch-through phenomenon occur. The punch through phenomenon affects the electric field at a channel region of a transistor and causes the electric potential to significantly increased. For example, in an access MOS transistor employed in a memory cell of DRAM, when the short channel effect is present, the threshold voltage of the DRAM cell becomes reduced and leakage current is increased, thereby degrading the refresh feature of DRAM. To solve this problem, a transistor having a recessed channel has been suggested which has an increased gate channel length formed in a substrate and has an increased integration degree at the same time.

An exemplary method for manufacturing a transistor having a recessed channel is as follows. Impurity is doped into the top of a substrate to form a source/drain region thereon. Subsequently, a mask opening in a region which is supposed to be a recess channel is formed on the top of the substrate, and the substrate is etched using a mask to form a trench in the substrate. Subsequently, a gate oxidation layer is formed on the inner wall of the trench. The gate oxidation layer can be formed of a high dielectric (high-K) material layer such as a silicon oxide layer, a hafnium dioxide layer, or a hafnium silicon oxide layer. Subsequently, a gate conductive layer is formed using a poly/metal stack layer or a metal/poly/metal stack layer. The poly/metal stack layer is similar to polysilicon in high dielectric characteristics but has resistance lower than polysilicon. By using a gate mask, the gate conductive layer is isotropically etched to form a gate electrode, so that a transistor having a gate electrode and a source/drain is obtained.

As described above, as the integration level of semiconductor devices increases, a high dielectric material layer needs to be employed as a gate oxidation layer in order to reduce gate leakage current and power consumption. Also, a stack structure in which polysilicon is laminated on metal is used as a gate conductive layer and formed on the high dielectric material layer. However, one problem in the method for manufacturing a transistor with the recessed channel is that the etching selectivity is insignificant between the metal layer serving as the gate conductive layer and the high dielectric material layer serving as the gate oxidation layer. Due to a low etching selectivity, when the gate conductive layer is etched, the substrate underlying the high dielectric material layer is attacked.

In the meantime, in case the thickness of the gate oxidation layer is reduced in order to improve the controllability of the gate, the electric field becomes concentrated between the neighboring gates, thereby causing Gate Induced Drain Leakage (GIDL). That is, a bridge between a word line and a bit line, or between word lines, is formed, and the GIDL current due to a direct tunneling between the gate electrode and the drain region is increased. The GIDL current significantly degrades a semiconductor device, especially in a DRAM device having a recessed channel.

### BRIEF SUMMARY OF THE INVENTION

Embodiments of the present invention are directed to a semiconductor device having a vertical gate and a method for forming the same that may solve the problem of deteriorating the characteristics of a semiconductor device due to GIDL.

According to an embodiment of the present invention, a semiconductor device includes: a vertical pillar protruded from a semiconductor substrate; a first junction region provided at an upper part of the vertical pillar; a second junction region provided proximate a lower part of the vertical pillar and apart from the first junction region; and

a gate oxidation layer wherein a thickness of the gate oxidation layer in a surface of the vertical pillar in which the first junction region is provided is thicker than that on a surface of the vertical pillar in which the first junction region is not provided. In accordance with an embodiment of the present invention, a semiconductor device further includes a barrier metal pattern provided over a sidewall of the vertical pillar to be overlapped with the first junction region; and
a gate pattern provided over the barrier metal pattern. In accordance with an embodiment of the present invention, a semiconductor device further includes a bit line metal layer spaced apart from the gate pattern and filling in a portion between the vertical pillars perpendicular to the gate pattern. In accordance with an embodiment of the present invention, a semiconductor device further includes a barrier metal layer provided on a sidewall and a bottom of the bit line metal layer. In accordance with an embodiment of the present invention, a semiconductor device further includes a gate pattern formed over the gate oxidation layerl; and a silicon nitride layer pattern provided over an upper part of the vertical pillar and extending to the gate pattern along the sidewall of the vertical pillar.

According to an embodiment of the present invention, a method for forming a semiconductor device includes: forming a first junction region on an upper part of a semiconductor substrate; etching the first junction region and the semiconductor substrate to form a silicon line pattern; etching the silicon line pattern to form a vertical pillar; forming a gate oxidation layer over a sidewall of the vertical pillar wherein a thickness of the gate oxidation layer over the vertical pillar in which the first junction region is provided is thicker than that over the vertical pillar in which the first junction region is not provided; and forming a gate pattern over the gate oxidation layer so as to be extend to the first junction region. Forming a first junction region comprises injecting impurity into the semiconductor substrate. In accordance with an embodiment of the present invention, a method for forming a semiconductor device further includes forming a polysilicon pattern on the a lower part of a sidewall of the silicon line pattern; and forming a bit line metal layer filling in a lower portion of a gap between neighboring silicon line patterns. In accordance with an embodiment of the present invention, a method for forming a semiconductor device further includes diffusing polysilicon into the lower part of the sidewall of the silicon line pattern to form a second junction region after forming the polysilicon pattern. In accordance with an embodiment of the present invention, a method for forming a semiconductor device further includes forming a liner insulating layer covering an upper part of the silicon line pattern after forming a bit line metal layer. Forming the vertical pillar includes forming an interlayer insulating layer so as to fill between the neighboring silicon line patterns; forming a mask pattern defining the vertical pillar over the upper part of the interlayer insulating layer; and etching the interlayer insulating layer, the first junction region, and the silicon line pattern using the mask pattern as a mask. Forming the gate oxidation layer includes performing a thermal oxidation process with respect to the vertical pillar.

According to another embodiment of the present invention, a method for forming a semiconductor device includes a conductive pillar pattern formed over a semiconductor substrate; a first junction region provided at a first height level of the conductive pillar pattern; a second junction region provided at a second height level of the conductive pillar pattern, wherein the second height level is different from the first height level; and a gate oxidation layer formed over a sidewall of the conductive pillar pattern and extending to the first and the second junction regions, wherein the gate oxidation layer at the first height level is thicker than the gate oxidation layer provided between the first and the second height levels. Wherein the conductive pillar pattern includes a third height level and a fourth height level between the first and the second height levels, wherein the third height level is located more proximate to the first height level than the fourth height level, wherein the gate oxidation layer between the first and the second height levels has a second thickness T2, wherein the gate oxidation layers at the first, the third and the fourth height levels have a first thickness T1, a third thickness T3 and a fourth thickness T4 respectively, and wherein T1 is thicker than T3, the T3 is thicker than T4. According to another embodiment of the present invention further includes a gate pattern over the gate oxidation layer and extending over the first junction region. Wherein the first junction region is a source region and the second junction region is a drain region. Wherein the conductive pillar pattern is formed of substantially the same material as the semiconductor substrate.

The present invention forms a gate oxidation layer using the oxidation rate difference without a mask process in order to minimize GIDL, which leads to improvement in the characteristics of a semiconductor device.

### BRIEF DESCRIPTION OF THE DRAWINGS

FIG. 1 is a cross-sectional view showing a semiconductor device according to the present invention, and (i) is a plan view, (ii) is a cross-sectional view taken along line x-x′ of (i), and (iii) is a cross-sectional view taken along line y-y′ of (i); and

FIGS. 2a through 2i are cross-sectional views showing a method for forming a semiconductor device according to the present invention, and (i) are plan views, (ii) are cross-sectional views taken along line x-x′ of (i), and (iii) are cross-sectional views taken along line y-y of (i), respectively.

### DESCRIPTION OF EMBODIMENTS

Exemplary embodiments of the present invention are described with reference to the accompanying drawings in detail.

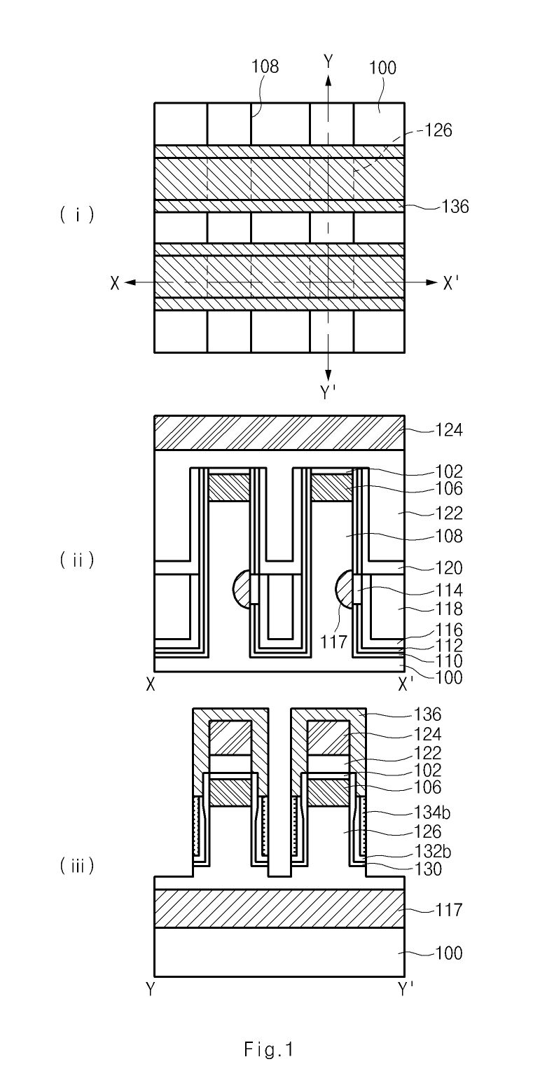

As shown in FIG. 1, it is preferred that a semiconductor device according to the present invention includes a vertical pillar 126 protruded from a semiconductor substrate 100; a first junction region 106 provided on the top of the vertical pillar 126; a second junction region 117 provided below the vertical pillar 126 to be separate from the first junction region 106; and a gate oxidation layer 130. In some embodiments, the vertical pillar 126 can be formed by etching the substrate 100 to the bottom of line pattern, so that the second junction region 117 can be located on a lower portion of the vertical pillar. The gate oxidation layer 130 is formed over a sidewall of the vertical pillar 126 and extending over a sidewall of first junction region 106. The thickness of the portion of gate oxidation layer 130 that is formed over the sidewall of the junction region 106 is greater than the thickness of the portion of gate oxidation layer 130 that is formed over the sidewall of the part of the vertical pillar 126 where the junction region 106 is not formed.

The semiconductor device of the present invention further includes a barrier metal pattern 132b provided over the gate oxidation layer 130 at the sidewall of the vertical pillar 126 and extended to the first junction region 106. A gate pattern 134b is formed over the barrier metal pattern 132b. The semiconductor device further includes a silicon nitride layer pattern 136 provided at the upper part of the gate pattern 134b to cover an upper part of the vertical pillar 126.

The present invention is not limited to the above-described embodiment. The gate oxidation layer is formed thicker at a region in which the concentration of impurity is high to prevent the electric field from being concentrated at that region and thus prevent GIDL.

The method of forming the semiconductor device having the above-described configuration is as follows.

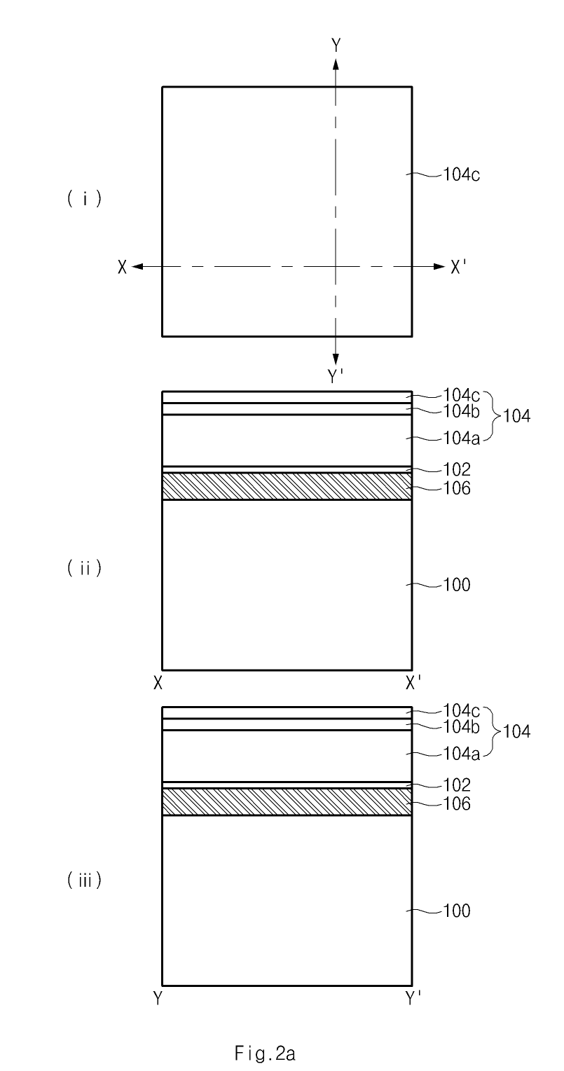

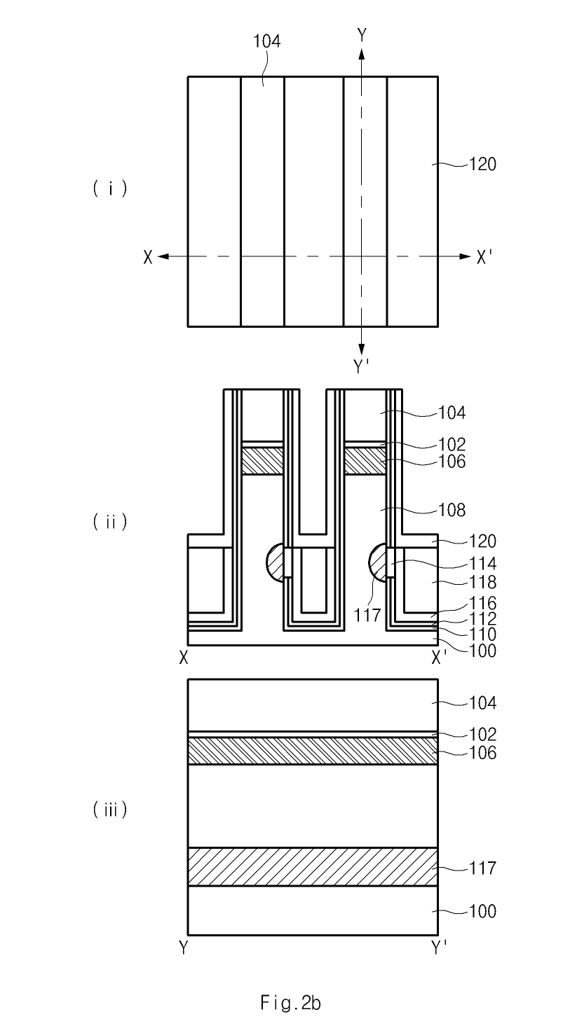

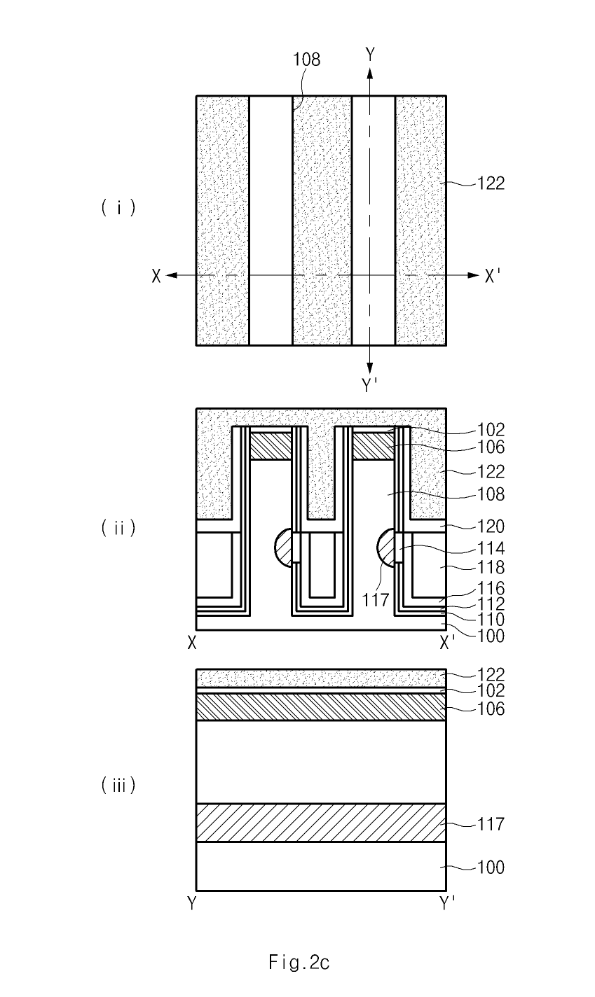

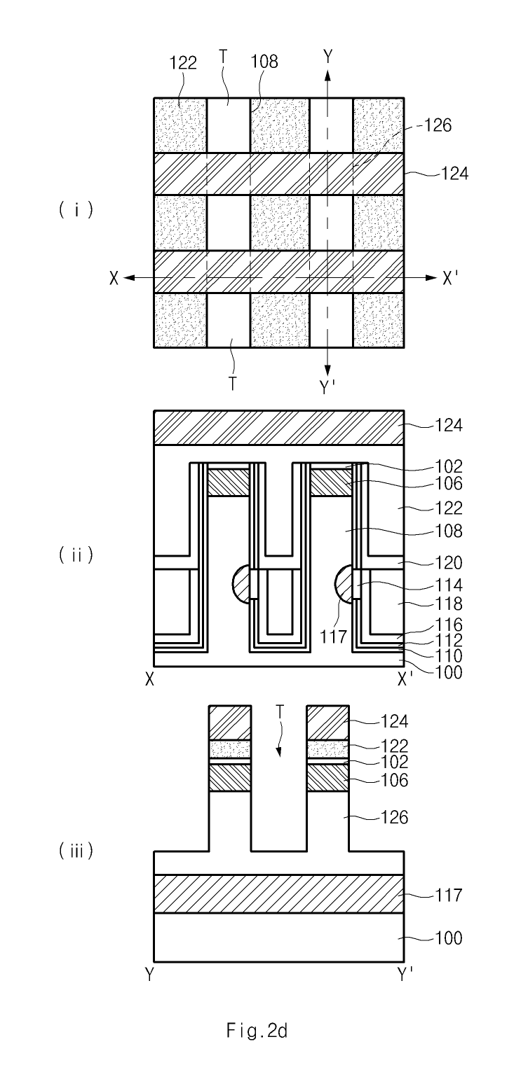

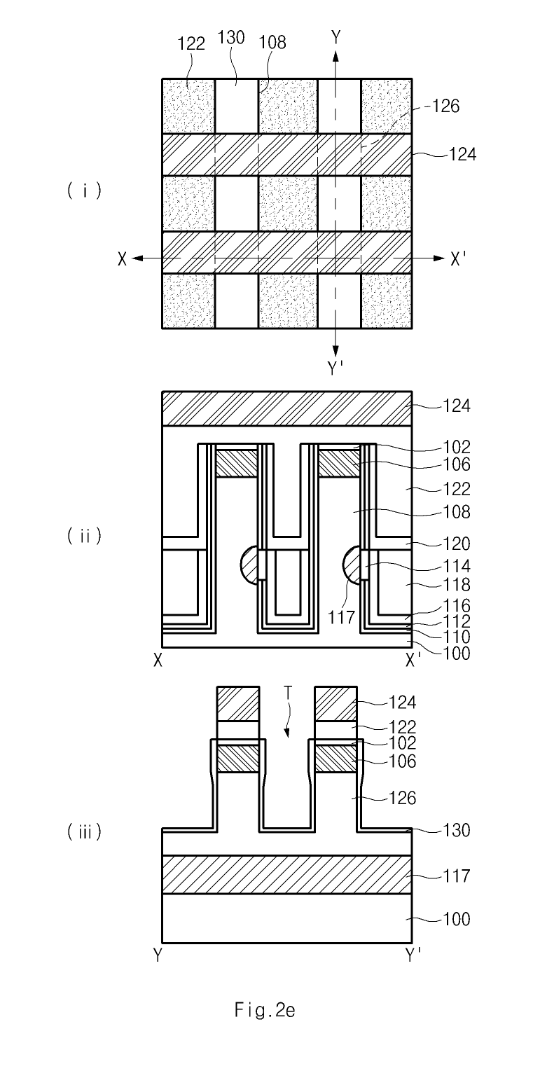

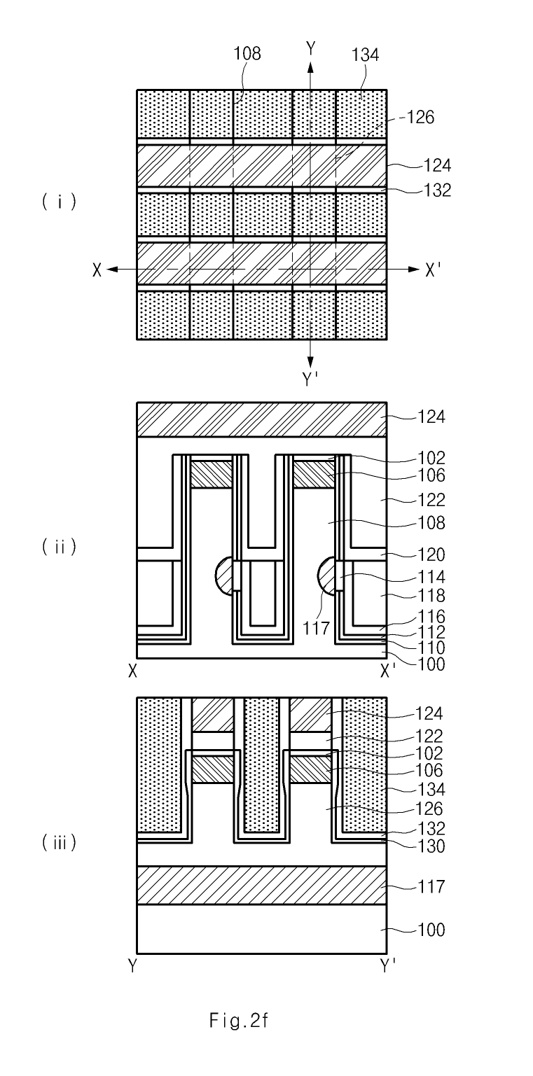

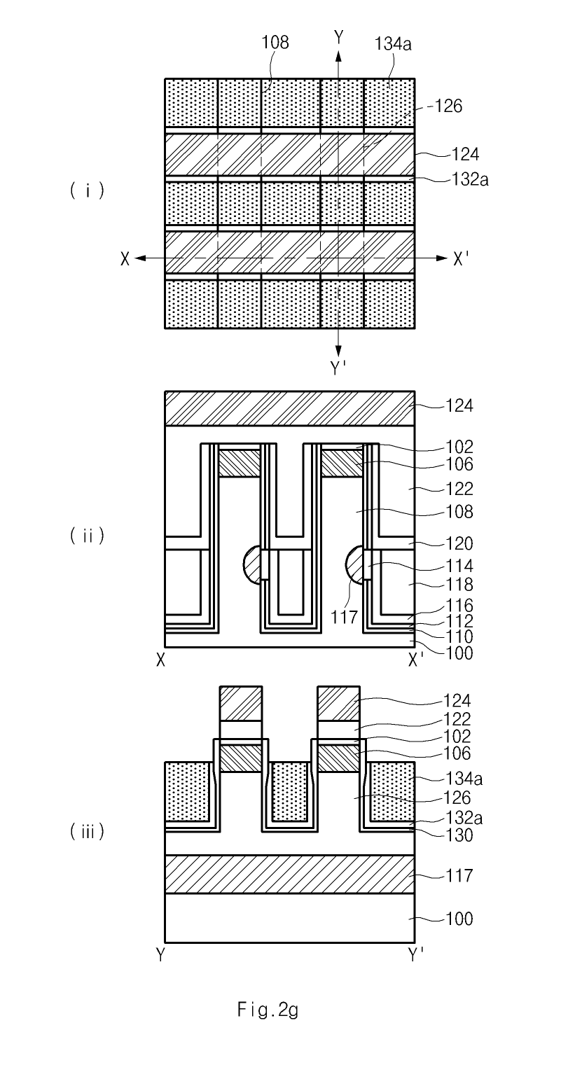

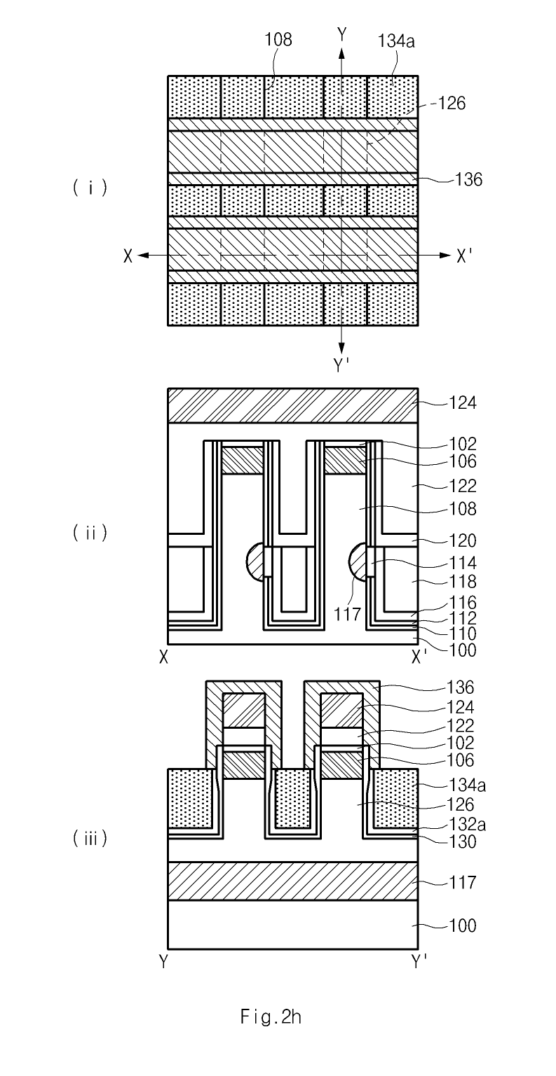

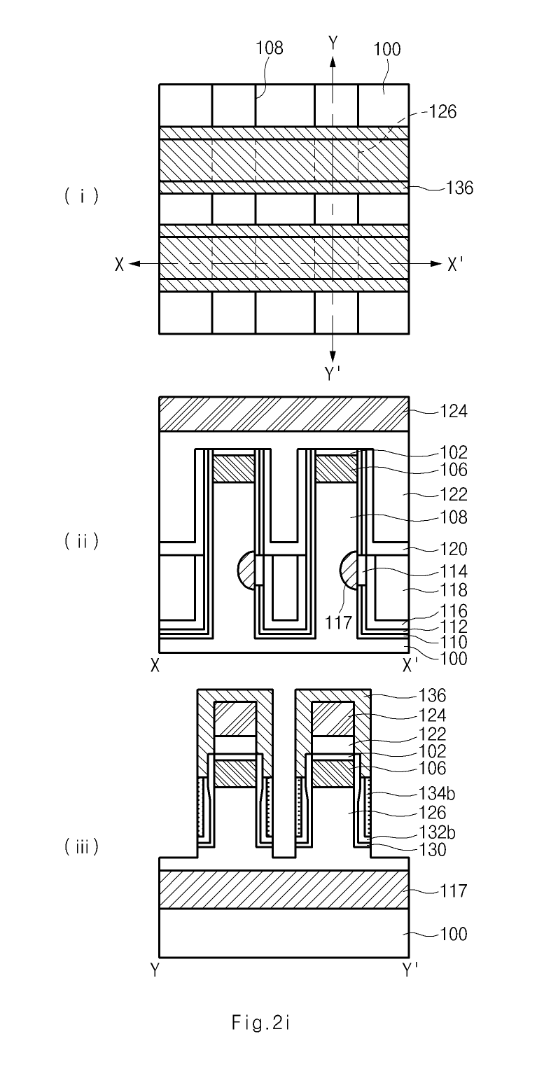

As shown in FIG. 2a, after formation of a pad oxide layer 102 on a semiconductor substrate 100, a hard mask layer 104 formed comprising a nitride layer 104a, an oxide layer 104b, and a carbon layer 104c is formed at an upper part of the pad oxide layer 102. Subsequently, the ion implantation is performed onto a surface of the semiconductor substrate 100 to form a first junction region 106. The process of forming the first junction region 106 facilitates oxidation, so as to form a thick gate oxidation film at a sidewall of the first junction region 106 during a subsequent process.

As shown in FIG. 2b, after a mask pattern (not shown) is formed at the upper part of the hard mask layer 104, the hard mask layer 104, the first junction region 106, and semiconductor substrate 100 are etched using the mask pattern as an etching mask to form a silicon line pattern 108. An oxide layer 110 is formed on the surface of the semiconductor substrate 100 on which the silicon line pattern 108 is formed, and a nitride layer 112 is formed on the oxide layer 110. As a result, a first sidewall of the nitride layer 112 and a first sidewall of the oxide layer 110 are formed on a first sidewall of the silicon line pattern 108, and a second sidewall of the nitride layer 112 and a second sidewall of the oxide layer 110 are formed on a second sidewall of the silicon line pattern 108. The first sidewall of the nitride layer 112 and the first sidewall of the oxide layer 110 are etched in the manner such that a window exposing the silicon line pattern 108 is formed through the first sidewall of the nitride layer 112 and the first sidewall of the oxide layer 110. By the window, the first sidewall of the nitride layer 112 is divided into a first lower sidewall disposed on the lower side of the window and a first upper sidewall disposed on the upper side of the window. In the same manner, the first sidewall of the oxide layer 110 is also divided into a first lower sidewall of the oxide layer 110 and a first upper sidewall of the oxide layer 110. Then, a conductive layer, for example, polysilicon is filled in the window to form a polysilicon pattern 114. The polysilicon pattern 114 can be formed by diffusing polysilicon material into the sidewall of the silicon line pattern 108 through the window, so that a second junction region 117 is formed on the sidewall of the silicon line pattern 108.

Next, a barrier metal layer 116 is formed on the first lower sidewall of the nitride layer 112 and the polysilicon pattern 114. The barrier metal layer 116 is also formed on a lower part of the second sidewall of the nitride layer 112. A bit line metal layer 118 is formed over the barrier metal layer 116 so as to be electrically coupled to the second junction region 117 through the polysilicon pattern 114 and the barrier metal layer 116. The bit line metal layer 118 can be formed of conductive material other than a metal. The bit line metal layer 118 can be formed in such a manner as partly filling in a gap between neighboring silicon line patterns 108. A liner insulating layer 120 is formed over the bit line metal layer 118 and extends over the first upper sidewall of the nitride layer 112. The liner insulating layer 120 is also formed over an upper portion of the second sidewall of the nitride layer 112. It is preferred that the liner insulating layer 120 is a silicon nitride layer.

As shown in FIG. 2c, the hard mask layer 104 has been removed. Then, the interlayer insulating layer 122 is formed in such a manner as to completely fill the gap between the neighboring silicon line patterns 108 and extending upward so as to cover the pad oxide layer 102 over the top of the silicon line pattern 108. It is preferred that the interlayer insulating layer 122 includes a spin-on-dielectric (SOD).

As shown in FIG. 2d, after a mask pattern 124 for defining a gate region is formed at the upper part of the interlayer insulating layer 122, the interlayer insulating layer 122, a pad oxide layer 102, and a silicon line pattern 108 are etched using the mask pattern 124 as mask. The silicon line pattern 108 is partly etched to form a vertical pillar 126 defined by a trench T. It is preferred that a bottom of the trench T is formed to be separated from an upper portion of the bit line metal layer 118. That is, the bottom of trench T is formed at a higher level than the top of the bit line metal layer 118.

As shown in FIG. 2e, a gate oxidation layer 130 is formed on two sides of the vertical pillar 126. The gate oxidation layer 130 is preferably formed by performing a thermal oxidation process. The thickness of the portion of gate oxidation layer 130 that is formed over the sidewall of the junction region 106 is greater than the thickness of the portion of gate oxidation layer 130 that is formed over the sidewall of the part of the vertical pillar 126 where the junction region 106 is not formed. It is because the upper and the lower portion of the vertical pillar 126 have different impurity concentration. That is, due to the first junction region 106 formed in upper portion of the vertical pillar 126, the upper portion of the vertical pillar 126 has a relatively higher impurity concentration and thus the oxidation occurs more actively in the upper portion of the vertical pillar 126 compared to the lower portion of the vertical pillar 126. As illustrated previously, by thickly forming the gate oxidation layer 130 over the first junction region 106, the electric field can be prevented from being concentrated on the upper portion of the vertical pillar and accordingly GIDL may be effectively prevented.

As shown in FIG. 2f, a barrier metal layer 132 is formed over a sidewall of the vertical pillar 126 over which the gate oxidation layer 130 is formed. A gate metal layer 134 is formed on the barrier metal layer 132 in such a manner as filling a gap between neighboring vertical pillars 126.

As shown in FIG. 2g, the etch back process is performed to partly remove the gate metal layer 134 and the barrier metal layer 132 to form a first gate metal pattern 134a and a first barrier metal pattern 132a. It is preferred that the etch-back process is performed so that the first gate metal pattern 134a and the first barrier metal pattern 132a are formed extending to the first junction region 106.

As shown in FIG. 2h, the silicon nitride layer pattern 136 is formed, as a mask, over the first barrier metal layer 132a and the first gate metal layer 134a.

As shown in FIG. 2i, the first barrier metal pattern 132a, the first gate metal pattern 134a, and the silicon line pattern 108 under the first gate metal pattern 134a are etched using the silicon nitride layer pattern 136 as an etching mask to form a second barrier metal pattern 132b and a second gate pattern 134b. It is preferred that the second barrier metal pattern 132b and the second gate pattern 134b are formed to etch the silicon line pattern 108 in order to be separated apart from the bit line metal layer 118.

The present invention provides a device with an increased thickness of the gate oxidation layer in the region with high impurity concentration, thereby preventing the electric field from focusing in the region with high impurity concentration and preventing the generation of the GIDL. The present invention is not limited to the above-described embodiments. As another embodiment, semiconductor device by controlling the thickness of the gate oxidation layer using a density difference of impurities is changeable.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A semiconductor device, comprising:
a vertical pillar protruded from a semiconductor substrate;
a first junction region provided at an upper portion of the vertical pillar;
a second junction region provided proximate a lower portion of the vertical pillar and apart from the first junction region; and
a gate oxidation layer,
wherein a thickness of the gate oxidation layer in a surface of the vertical pillar in which the first junction region is provided is thicker than that on a surface of the vertical pillar in which the first junction region is not provided.

2. The semiconductor device of claim 1, further comprising:
a barrier metal pattern provided over a sidewall of the vertical pillar to be overlapped with the first junction region; and
a gate pattern provided over the barrier metal pattern.

3. The semiconductor device of claim 2, further comprising a bit line metal layer spaced apart from the gate pattern and filling in a portion between the vertical pillars perpendicular to the gate pattern.

4. The semiconductor device of claim 3, further comprising a barrier metal layer provided on a sidewall and a bottom of the bit line metal layer.

5. The semiconductor device of claim 1, further comprising:
a gate pattern formed over the gate oxidation layer; and
a silicon nitride layer pattern provided over an upper portion of the vertical pillar and extending to the gate pattern along the sidewall of the vertical pillar.

6. A method for forming a semiconductor device, comprising:
forming a first junction region in an upper part of a semiconductor substrate;
etching the first junction region and the semiconductor substrate to form a silicon line pattern;
etching the silicon line pattern to form a vertical pillar;
forming a gate oxidation layer over a sidewall of the vertical pillar, wherein a thickness of the gate oxidation layer over the vertical pillar in which the first junction region is provided is thicker than that over the vertical pillar in which the first junction region is not provided; and
forming a gate pattern over the gate oxidation layer so as to be extend to the first junction region.

7. The method of claim 6, wherein forming a first junction region comprises injecting impurity into the semiconductor substrate.

8. The method of claim 6, the method further comprising:
forming a polysilicon pattern on a lower part of a sidewall of the silicon line pattern; and
forming a bit line metal layer filling in a lower portion of a gap between neighboring silicon line patterns.

9. The method of claim 8, the method further comprising diffusing polysilicon into the lower part of the sidewall of the silicon line pattern to form a second junction region after forming the polysilicon pattern.

10. The method of claim 8, the method further comprising forming a liner insulating layer covering an upper part of the silicon line pattern after forming a bit line metal layer.

11. The method of claim 10, wherein forming the vertical pillar comprises:
forming an interlayer insulating layer over the upper part of the liner insulating layer so as to fill between the neighboring silicon line patterns;
forming a mask pattern defining the vertical pillar over the upper part of the interlayer insulating layer; and
etching the interlayer insulating layer, the first junction region, and the silicon line pattern using the mask pattern as a mask.

12. The method of claim 11, wherein forming the gate oxidation layer includes performing a thermal oxidation process with respect to the vertical pillar.

13. A semiconductor device, comprising:
a conductive pillar pattern formed over a semiconductor substrate;
a first junction region provided at a first height level of the conductive pillar pattern;
a second junction region provided at a second height level of the conductive pillar pattern, wherein the second height level is different from the first height level; and
a gate oxidation layer formed over a sidewall of the conductive pillar pattern and extending to the first and the second junction regions,
wherein the gate oxidation layer at the first height level is thicker than the gate oxidation layer provided between the first and the second height levels.

14. The semiconductor device of claim 13, wherein the conductive pillar pattern includes a third height level and a fourth height level between the first and the second height levels,
wherein the third height level is located more proximate to the first height level than the fourth height level,
wherein the gate oxidation layer between the first and the second height levels has a second thickness T2,
wherein the gate oxidation layers at the first, the third and the fourth height levels have a first thickness T1, a third thickness T3 and a fourth thickness T4 respectively, and
wherein T1 is thicker than T3, the T3 is thicker than T4.

15. The semiconductor device of claim 13, further comprising:
a gate pattern over the gate oxidation layer and extending over the first junction region.

16. The semiconductor device of claim 13,
wherein the first junction region is a source region and the second junction region is a drain region.

17. The semiconductor device of claim 13, wherein the conductive pillar pattern is formed of substantially the same material as the semiconductor substrate.
